(19) United States
(12) Patent Application Publication
(10) Pub. No.: US 2002/0112955 A1
(43) Pub. Date: Aug. 22, 2002

(54) Rejuvenation of refractory metal products

(75) Inventors: Paul Aimone, Bridgewater, MA (US); Prabhat Kumar, Framingham, MA (US); Peter R. Jepson, Newbury, MA (US); Henning Uhlenhut, Cambridge, MA (US); Howard V. Goldberg, Framingham, MA (US)

Correspondence Address: PERKINS, SMITH & COHEN LLP, ONE BEACON STREET, 30TH FLOOR, BOSTON, MA, 02108, US

(73) Assignee: H.C. Starck, Inc.

(21) Appl. No.: 10/075,709

(22) Filed: Feb. 14, 2002

Related U.S. Application Data
(60) Provisional application No. 60/268,742, filed on Feb. 14, 2001.

(51) Int. Cl. C23C 14/34; B22F 1/00

(52) U.S. Cl. 204/298.12; 204/298.13; 419/1; 419/61

(57) ABSTRACT

Refractory metal products, such as tantalum on non-refractory conductive metal backings, e.g. copper, can be rejuvenated after metal consumption in selected zones by powder filling the zones and high energy heating at high scan speed to sinter the added powder, without complete melting of the powder fill, thus establishing a microstructure consistent with the balance of the reclaimed product and avoiding the separation of the copper backing and tantalum sputter plate. The rejuvenation method can be applied to non-mounted refractory metal products that are subject to non-uniform erosion, etching, chipping or other metal loss. The form of such refractory metal products can be as plate, rod, cylinder, block or other forms apart from sputter targets. The process can be applied to, for example, x-ray disks or targets (molybdenum plate on carbon backing).

### CROSS REFERENCE TO RELATED APPLICATIONS

This application claims priority of Provisional Application No. 60/268,742, entitled “REJUVENATION OF SPUTTERING TARGETS” filed on Feb. 14, 2001, and which is incorporated herein by reference.

### FIELD AND BACKGROUND OF THE INVENTION

The purpose of the invention is to decrease the recycling cost of refractory metal products, and in particular, rejuvenating sputtering targets having backing plate structures attached.

For example, sputtering targets of high temperature materials, such as tantalum and other refractory metals (Ta, Nb, Ti, Mo, Zr, metals and alloys; hydrides, nitrides and other compounds thereof) used in integrated circuit manufacture and other electrical, magnetic and optical product manufacture usually are eroded in a non-uniform way during the process of sputtering which leads to a race track like trench on the operating side of the target. In order to prevent any contamination of the substrates or catastrophic break-through of coolant fluids behind the target, the targets generally are withdrawn from service well before the refractory sputter metal is penetrated, accepting the need for a new target after only a minor portion of the sputter metal has been consumed. The major part of the sputter target can be resold only at scrap price or recycled with difficulty and apart from this, the backing plate of the target needs to be removed and may be re-bonded to a new sputter metal plate for recycling.

It is a principal object of the invention to replace such current recycling practice by rejuvenation of sputtering targets as described below.

It is an object of the invention to improve the cost and speed of getting used sputtering targets back into service.

It is a further object of the invention to establish a microstructure of the fill zone at least as good as on the balance of the target.

### SUMMARY OF THE INVENTION

The present invention is a method to rejuvenate surfaces of used refractory metal products by filling consumed surface areas with consolidated powder metal. For example, a race track trench or other erosion zone is produced on the face of a sputtering target after numerous non-uniform bombardments of argon atoms. The consumed surface is rejuvenated by the placement or deposition of sputter metal and sinter bonding by laser or EB heating for sintering or plasma discharge coupled with deposition. Use of these methods will yield a fully dense coating. This avoids the need for decoupling the tantalum from the copper, filling the erosion zone of the tantalum plate with tantalum powder and HIP (hot isostatic pressing) bonding and reassembly. In the case of laser or EB scan sintering or plasma discharge coupled with deposition the target can be rejuvenated without separating the backing plate from the target. The various forms of rejuvenation produce a filled erosion zone with microstructure similar to the balance of the target.

The invention can be applied to refractory metal products generally (whether or not mounted on a non-refractory metal carrier) that are subject to non-uniform erosion, etching, chipping or other metal loss. The form of such refractory metal products can be as plate, rod, cylinder, block or other forms apart from sputter targets. The process can be applied to, for example, x-ray disks or targets (molybdenum plate on carbon backing).

The rejuvenation of a refractory metal product (e.g. tantalum target) eliminates the need to recycle the whole product after only a minor share of the product has been consumed. Such rejuvenation can be more economical than recycling the whole target. Separation of the bonded backing plate (e.g. copper), if any, may not be needed. This rejuvenation can be practiced repeatedly, as many times as desired.

Other objects, features and advantages will be apparent from the following detailed description of preferred embodiments taken in conjunction with the accompanying drawings in which:

### BRIEF DESCRIPTION OF THE DRAWINGS

FIG. 1 shows a cross section of typical target and backing plate;

FIG. 2 shows a face view including a usual erosion zone;

FIG. 3 is a block diagram of the rejuvenation process; and

FIG. 4 shows in outline form a vacuum or inert gas chamber set-up for practice of the invention.

### DETAILED DESCRIPTION OF PREFERRED EMBODIMENTS

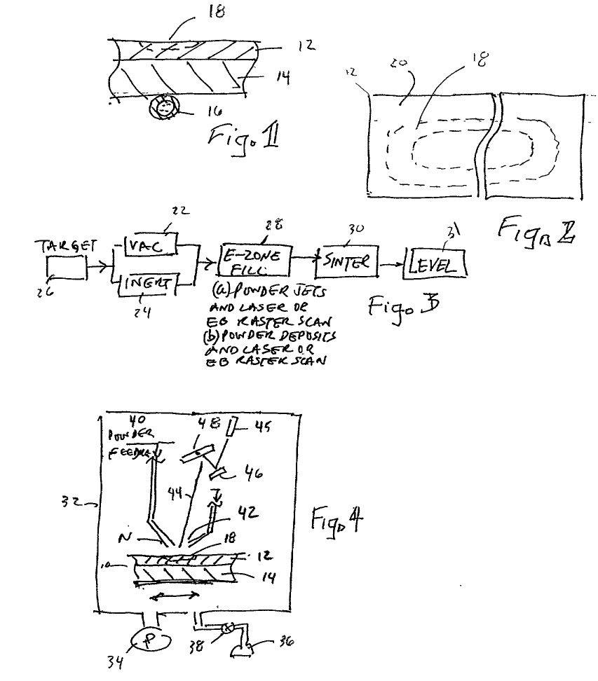

Now turning to FIGS. 1 and 2, a tantalum (Ta) sputter plate 12 bonded to a copper (Cu) backing plate 14 is presented to illustrate the rejuvenation process of the present invention. In addition to the backing plate, the sputter target may include additional complexity such as bonded-on water cooling coils 16 or even be part of a large cooling liquid reservoir and/or have complex flanges and mechanical and electrical attaching structures. 18 indicates a typical racetrack form erosion zone or consumed area on the target surface 20 of the sputter plate 12 arising from sputtering usage.

A flow chart of the implementation of the preferred embodiment of the present invention is illustrated in FIG. 3. A vacuum 22 or inert gas zone 24 is established for a used Ta-Cu target 26 assembly. The erosion zone 18 or consumed area of the sputter plate 12, as shown in FIG. 2, is filled with powders of the sputter metal. The powders are bonded or sintered 30 to the sputter plate 12 by laser or electron beam raster scanning to melt powder surfaces, but not complete particles or the entire particle that act as nuclei for grain growth. The melting can be done during powder deposition or after deposition on a layer-on-layer basis. A powder derived foil can also be pre-made and laid into the trench. In all cases the fill is sintered for self bonding and adhesion to the target and leveled off by machining, sanding or other abrasion etching and/or a burn-in sputtering process.

The following is one of several examples of how the invention can be implemented.

As shown in FIG. 4, a sputtering target 10 can be placed in a vacuum chamber 32 evacuated atmospheric pressure purified inert gas (argon) atmosphere utilizing conventional pump 34 and gas back-fill apparatus 36 with valve 38. A powder feeder 40 comprising multiple nozzles 42 can insert multiple high velocity streams of Ta powder of −100 to 325 mesh to the erosion zone 18 or consumed area. The powder feeder 40 can scan along the erosion zone 18 or the target can be moved relative to a fixed powder feeder. A 15-20 KW (preferably 20-25) laser beam 44 formed by a laser 45 and conventional scan optics 46, 48 which can be wholly in the chamber 32 or partly outside the chamber 32 using a window for beam passage can be traced in raster scan fashion over the erosion zone 18, as the powder falls, to melt powder particle surfaces and enable particle to particle bonding and bonding to the base of the erosion zone continuously and repeatedly around the zone 18 until it is filled. Powder mass calculations and/or optical monitors can be used to determine completion and a cut-off of filling.

One form of equipment usable for such processing is the Lasform brand direct metal deposition system of AeroMet Corp., as described, e.g., in Abbott et al., “Laser Forming Titanium Components” in the May 1998 issue of Advanced Metals & Processes and Arcella et al., “Producing Titanium Aerospace Components From Powder Using Laser Forming,” Journal of Metals (May 2000), pp. 28-30.

The laser can provide post-fill heating to complete the sintering. Separate target heaters can be used to preheat the target or provide additional heat during the rejuvenation.

The various forms of rejuvenation produce a filled erosion zone or consumed area with microstructure similar to the balance of the target. For example, filled erosion zone specimens from a sputtering target were analyzed for the electron beam raster scanning method. The hardness was typical for rolled and annealed tantalum plate with normal variation. The filled erosion zones were substantial free of porosity and inclusions. The yield strength and ultimate yield strength met ASTM requirements.

In another embodiment of the invention, the well unknown process of plasma deposition can be utilized to combine the powder placement and fusing steps.

It will now be apparent to those skilled in the art that other embodiments, improvements, details, and uses can be made consistent with the letter and spirit of the foregoing disclosure and within the scope of this patent, which is limited only by the following claims, construed in accordance with the patent law, including the doctrine of equivalents.

What is claimed is:

1. A rejuvenated tantalum sputtering target comprising:
a used tantalum sputtering target having a tantalum sputtering plate and a backing plate, wherein a target face of said tantalum sputtering plate includes one or more consumed surface area portions; and
a mass of bonded metal particles within each of said one or more consumed surface area portions, wherein said mass of bonded metal particles partially or completely fills each of said one or more consumed surface area portions,
whereby said used tantalum sputtering target is rejuvenated without separating said backing plate from said tantalum sputtering plate.

2. The rejuvenated tantalum sputtering target as defined in claim 1, wherein said mass of bonded metal particles has microstructure substantially similar to said tantalum sputtering plate.

3. A method to rejuvenate a consumed tantalum sputtering target comprising the steps:
providing a used tantalum sputtering target having a tantalum sputtering plate and a backing plate, wherein a target face of said tantalum sputtering plate includes one or more consumed surface area portions;
providing a powder of refractory metal having microstructure substantially similar to the tantalum sputtering plate;
filling each of one or more consumed surface area portions with said powder of refractory metal to form filled portions; and
applying a short term, high powered radiant energy beam locally to said filled portions to bond powder particles of said powder of refractory metal to each other and to said each of one or more consumed surface area portions to form a mass of bonded metal particles,
whereby said used tantalum sputtering target is rejuvenated without separating said backing plate from said tantalum sputtering plate.

4. The method of rejuvenating a consumed tantalum sputtering target as defined in claim 3 further comprising the step removing excess of said mass of bonded metal particles to level said tantalum sputtering plate.

5. The method of rejuvenating a consumed tantalum sputtering target as defined in claim 3 wherein said energy beam is laser beam.

6. The method of rejuvenating a consumed tantalum sputtering target as defined in claim 3 wherein said energy beam is electron beam.

7. The method of rejuvenating a consumed tantalum sputtering target as defined in claim 3 wherein the bonding step is plasma deposition.

8. The method of rejuvenating a consumed tantalum sputtering target as defined in claim 3 wherein said energy beam is applied in a vacuum environment.

9. The method of rejuvenating a consumed tantalum sputtering target as defined in claim 3 wherein said energy beam is applied in an inert gas environment.

10. The method of rejuvenating a consumed tantalum sputtering target as defined in claim 3 wherein said powder of refractory metal is in the form of a powder-derived foil, wherein said powder-derived foil is laid individually in said each of one or more consumed surface area portions and bonded to the sputter plate, whereby said filling and bonding steps are repeated until said consumed surface area portions are partially or completely filled.

11. The method of rejuvenating a consumed tantalum sputtering target as defined in claim 4 wherein the step removing excess of said mass of bonded metal particles to level the sputter plate is machining.

12. The method of rejuvenating a consumed tantalum sputtering target as defined in claim 4 wherein the step removing excess of said mass of bonded metal particles to level the sputter plate is sanding.

13. The method of rejuvenating a consumed tantalum sputtering target as defined in claim 4 wherein the step removing excess of said mass of bonded metal particles to level the sputter plate is abrasion etching.

14. The method of rejuvenating a consumed sputtering target as defined in claim 4 wherein the step removing excess of said mass of bonded metal particles to level the sputter plate is burn-in sputtering.

15. A rejuvenated sputtering target having a mass of bonded metal particles filling each of one or more consumed surface area portions of a used sputtering target with the particles bonded to each other and to the surface area(s), as produced in accordance with the method of claim 3.

16. A process for rejuvenating a refractory metal sputtering target having one or more consumed surface area portions comprising the steps of:
filling each of one or more consumed surface area portions with powder metal, the powder metal being of the same composition as the refractory metal sputtering target to form filled portions;
applying a short term, high powered radiant energy beam in vacuum or inert gas atmosphere locally to the filled portions to bond powder particles of the powder of refractory metal to each other and to each of one or more consumed surface area portions; and
leveling of the sputtering target to remove high points of the bond powder particles.

17. The process of claim 16 wherein the sputtering target is selected from the group consisting of tantalum and niobium and their alloys.

18. The process of claim 16 wherein the energy beam is selected from the group consisting of laser beam and electron beam.

19. The process of claim 16 wherein the leveling step is selected from the group consisting of machining, sanding, abrasion etching and burn-in sputtering.

20. A rejuvenated sputtering target having a fully dense coating filling each of one or more consumed surface area portions of a used sputtering target with the fully dense coating bonded to the surface area(s) in accordance with the method of claim 16.

21. A method to rejuvenate a refractory metal product having one or more locally consumed surface area portions comprising the steps of:
selectively supplying a powder of refractory metal to partially or completely fill each of said one or more consumed surface area portions of the refractory metal product to form filled portions; and
applying a short term, high powered radiant energy beam locally to said filled portions to bond powder particles of said powder of refractory metal to each other and to each of said one or more consumed surface area portions.

22. The method of claim 21 as applied to a laminate of refractory metal to non-refractory metal.

23. The method of claim 21 wherein the radiant energy beam is a laser beam.

24. The method of claim 21 wherein the radiant energy beam is an electron beam.
